(19) United States
(12) Patent Application Publication
(10) Pub. No.: US 2025/0098289 A1
(43) Pub. Date: Mar. 20, 2025

(54) SEMICONDUCTOR DEVICE

(71) Applicant: KABUSHIKI KAISHA TOSHIBA, Tokyo (JP)

(72) Inventors: Yusuke KOBAYASHI, Yokohama (JP); Tomoaki INOKUCHI, Yokohama (JP); Tatsunori SAKANO, Tokyo (JP); Satoshi YOSHIDA, Kawasaki (JP); Kento ADACHI, Tokyo (JP); Hiro GANGI, Tokyo (JP); Shotaro BABA, Kawasaki (JP); Taichi FUKUDA, Yokohama (JP)

(73) Assignee: KABUSHIKI KAISHA TOSHIBA, Tokyo (JP)

(21) Appl. No.: 18/589,752

(22) Filed: Feb. 28, 2024

(30) Foreign Application Priority Data
Sep. 19, 2023 (JP) 2023-151434

(51) Int. Cl. H01L 27/06; H01L 23/00; H01L 29/40; H01L 29/78

(52) U.S. Cl. CPC H10D 84/811; H01L 24/48; H10D 1/47; H10D 1/692; H10D 30/668; H10D 64/117; H01L 2224/4813; H01L 2924/1205; H01L 2924/1207; H01L 2924/13091; H01L 2924/30107

(57) ABSTRACT

An embodiment includes a transistor section, a gate electrode pad, a gate connection member, a gate circuit section, and a casing. The transistor section includes a drain electrode, a source electrode and a gate electrode. The transistor section and the gate electrode pad are provided on a semiconductor substrate. The gate connection member connects a gate terminal and the gate electrode pad. The gate circuit section connects the gate electrode pad and the gate electrode, and includes a parallel circuit with a capacitor and a resistive element, a first connection member electrically connecting the capacitor to the gate electrode pad and a second connection member electrically connecting the capacitor to the gate electrode. The casing accommodates the transistor section, the gate electrode pad and the gate circuit section.

### CROSS-REFERENCE TO RELATED APPLICATIONS

This application is based upon and claims the benefit of priority from Japanese Patent Application No. 2023-151434, filed on Sep. 19, 2023; the entire contents of which are incorporated herein by reference.

### FIELD

Embodiments relate to a semiconductor device.

### BACKGROUND

A metal oxide semiconductor field effect transistor (MOSFET) is an example of a semiconductor device for power which is capable of performing high-speed switching. The MOSFET can be switched at a high speed by lowering output impedance of a circuit that drives a gate.

On the other hand, a wiring that is connected to each electrode of the MOSFET has finite inductance, and due to the inductance, high-speed switching may cause ringing or element destruction due to a surge voltage.

There is a strong demand to reduce a switching loss by switching the MOSFET at a high speed.

### BRIEF DESCRIPTION OF THE DRAWINGS

FIG. 1 is a schematic plan view illustrating a semiconductor device according to a first embodiment;

FIG. 2 is a schematic circuit diagram illustrating an equivalent circuit of the semiconductor device according to the first embodiment;

FIG. 3 is a schematic cross-sectional view taken along line AA in FIG. 1;

FIG. 4 is a schematic cross-sectional view taken along line BB in FIG. 1;

FIG. 5A to FIG. 5C are schematic cross-sectional views illustrating a capacitor that is a part of a semiconductor device according to a variation of the first embodiment;

FIG. 6 is a circuit diagram for simulating characteristics in switching of the semiconductor device according to the first embodiment;

FIG. 7 is a graph of a characteristic example in switching in a case where an inductance value from a gate circuit section in the circuit illustrated in FIG. 6 is set as a parameter;

FIG. 8A to FIG. 8C are schematic plan views illustrating semiconductor devices according to variations of the first embodiment;

FIG. 9A to FIG. 9C are schematic plan views illustrating semiconductor devices according to variations of the first embodiment;

FIG. 10 is a schematic perspective view illustrating a semiconductor device according to a second embodiment;

FIG. 11 is a schematic cross-sectional view of a capacitor that is a part of the semiconductor device in FIG. 10; and

FIG. 12A and FIG. 12B are schematic perspective views illustrating semiconductor devices according to variations of the second embodiment.

### DETAILED DESCRIPTION

A semiconductor device according to embodiments includes: a transistor section including a source electrode that is provided on a first face of a semiconductor substrate and is electrically connected to a source terminal, a drain electrode that is provided on a second face opposite to the first face in the semiconductor substrate and is electrically connected to a drain terminal, and a gate electrode that is provided between the source electrode and the drain electrode; a gate electrode pad that is provided on the first face; a gate connection member that electrically connects the gate electrode pad and a gate terminal; a gate circuit section that is provided on the first face and is electrically connected between the gate electrode pad and the gate electrode; and a casing that accommodates the transistor section, the gate electrode pad, and the gate circuit section. The gate circuit section includes a capacitor, a resistive element that is connected to the capacitor in parallel, a first connection member that electrically connects one electrode of the capacitor to the gate electrode pad, and a second connection member that electrically connects the other electrode of the capacitor to the gate electrode.

Hereinafter, respective embodiments of the invention will be described with reference to the accompanying drawings.

The drawings are schematic and conceptual, and a relationship between the thickness and width of respective portions, a size ratio between the portions, and the like are not necessarily the same as real values. Even when the same portion is shown, dimensions and ratios may be shown differently depending on the drawings.

In the specification and the drawings, the same reference numeral will be given to the same elements which are described already, and detailed description will be appropriately omitted.

### First Embodiment

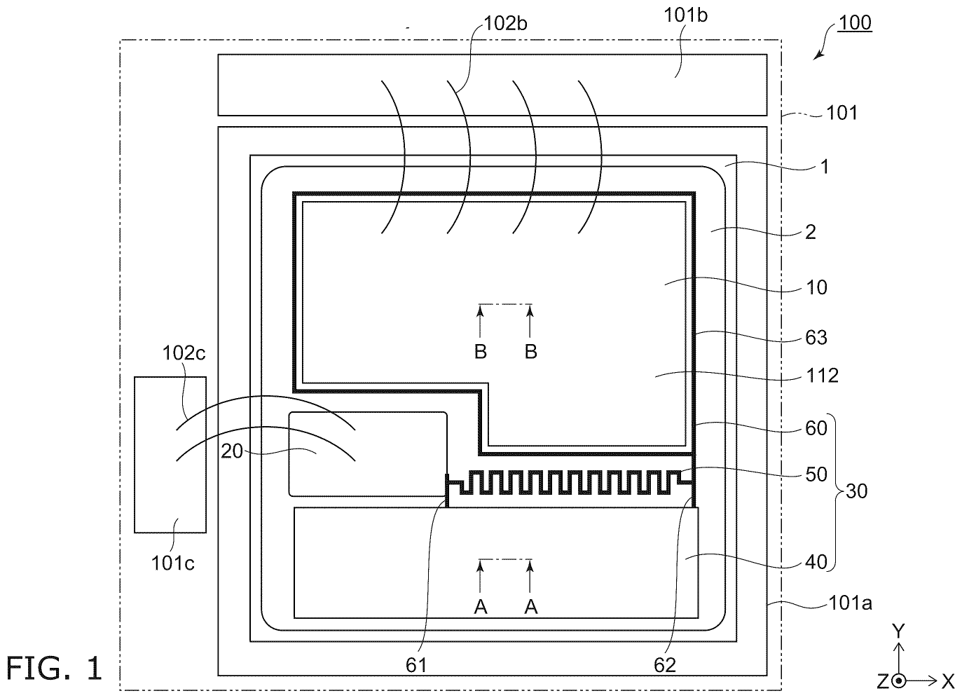

FIG. 1 is a schematic plan view illustrating a semiconductor device according to a first embodiment.

As shown in FIG. 1, a semiconductor device 100 according to the embodiment includes a transistor section 10, a gate electrode pad 20, and a gate circuit section 30. In the embodiment, the transistor section 10, the gate electrode pad 20, and the gate circuit section 30 are provided on a semiconductor substrate 1. The semiconductor substrate 1 contains, for example, Si.

In the semiconductor substrate 1, as described later with reference to FIG. 3, a source electrode 112 of the transistor section 10 is provided on a front face side of the semiconductor substrate 1. A drain electrode 111 of the transistor section 10 is provided on a rear face of the semiconductor substrate 1. The transistor section 10 is, for example, MOSFET.

Hereinafter, description will be made by using an XYZ coordinate system. The front face of the semiconductor substrate 1 shown in FIG. 3 is a first face 1a, and the rear face is a second face 1b. An XY-plane is parallel to the first face 1a. A positive direction of a Z-axis is a direction from the second face 1b toward the first face 1a.

In a specific example in FIG. 1, the semiconductor device 100 includes a mount bed 101a, a source terminal 101b, and a gate terminal 101c. The semiconductor substrate 1 is provided on the conductive mount bed 101a. The drain electrode 111 provided on the second face 1b of the semiconductor substrate 1 is electrically connected to the mount bed 101a through a joining member such as solder. The mount bed 101a functions as a drain terminal of the transistor section 10.

The source terminal 101b is provided adjacent to the mount bed 101a with an interval in a Y-axis direction. A source connection wire 102b is provided between the source terminal 101b and the source electrode 112. The source connection wire 102b electrically connects the source terminal 101b and the source electrode 112.

A length of the source connection wire 102b is sufficiently short. Favorably, multiple source connection wires 102b are provided. When the multiple source connection wires 102b having a short length are provided, an inductance value from the source electrode 112 to the source terminal 101b can be made small. A wide ribbon-shaped connection member may be used instead of the source connection wire 102b. With regard to the inductance value of the connection member, since the inductance value of the connection member is smaller as the width of the connection member is larger, the inductance value of the connection member can be further reduced by setting the connection member to the wide ribbon shape.

The gate terminal 101c is provided adjacent to the mount bed 101a with an interval in an X-axis direction. A gate connection wire (gate connection member) 102c is provided between the gate terminal 101c and the gate electrode pad 20, and the gate connection wire 102c electrically connects the gate terminal 101c and the gate electrode pad 20.

A length of the gate connection wire 102c is sufficiently short. Favorably, multiple gate connection wires 102c are provided. When the multiple gate connection wires 102c having a short length are provided, an inductance value from the gate electrode pad 20 to the gate terminal 101c can be made small. A wide ribbon-shaped connection member may be used instead of the gate connection wire 102c. Since each of the gate connection wires 102c is connected to a gate wiring 60 in series, an inductance value of a series circuit of the gate connection wire 102c and the gate wiring 60 can be made small by making the inductance value of the gate connection wire 102c small.

The mount bed 101a on which the semiconductor substrate 1 is mounted, the source terminal 101b, the source connection wire 102b, the gate terminal 101c, and the gate connection wire 102c are accommodated in a casing 101. The casing 101 includes, for example, an epoxy resin or the like. In FIG. 1, the casing 101 is shown by a two-dot chain line to clearly illustrate the semiconductor substrate 1, the mount bed 101a, the source terminal 101b, the source connection wire 102b, the gate terminal 101c, and the gate connection wire 102c.

The gate circuit section 30 includes a capacitor 40, a resistive element 50, and a gate wiring 60. The gate wiring 60 includes wirings 61, 62, and 63.

In plan view, the transistor section 10, the gate electrode pad 20, the capacitor 40, and the resistive element 50 are disposed on the semiconductor substrate 1 so as not to overlap each other. The disposition in which the circuit constituting elements do not overlap each other represents that the respective circuit constituting elements are disposed to be spaced apart from each other in a plane direction of the semiconductor substrate 1 (in plan view).

The capacitor 40 is disposed adjacent to the gate electrode pad 20. The resistive element 50 is disposed adjacent to the gate electrode pad 20. The resistive element 50 is disposed also adjacent to the transistor section 10. In the specific example in FIG. 1, the gate electrode pad 20 and the resistive element 50 are disposed on a positive direction side of the Y-axis of the capacitor 40. The gate electrode pad 20 and the resistive element 50 are disposed in parallel in an X-direction. The transistor section 10 is disposed on a positive direction side of the Y-axis of the gate electrode pad 20 and the resistive element 50.

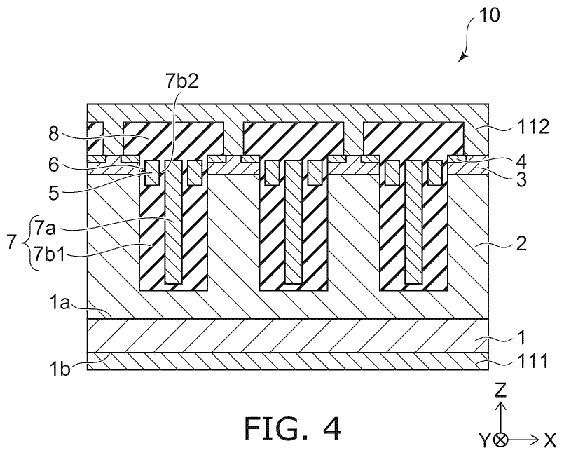

The wiring 63 surrounds an outer periphery of the transistor section 10. As to be described later with reference to FIG. 3 and FIG. 4, the wiring 63 is electrically connected to a gate electrode 5 of the transistor section 10, and leads the gate electrode 5 from the transistor section 10 to the outside.

The wiring (first wiring member) 61 is provided between the gate electrode pad 20 and the capacitor 40, and electrically connects the gate electrode pad 20 and the capacitor 40.

The wiring (second wiring member) 62 is provided between the transistor section 10 and the capacitor 40, and electrically connects the wiring 63 connected to the gate electrode of the transistor section 10, and the capacitor 40.

The wirings 61, 62, and 63 have a sufficiently small inductance value. According to this, an inductance value of the gate wiring 60 is sufficiently small.

The resistive element 50 is provided between the wirings 61 and 62, is electrically connected to the wirings 61 and 62 at both ends of the resistive element 50, and is connected to the capacitor 40 in parallel.

A circuit configuration of the semiconductor device 100 will be described.

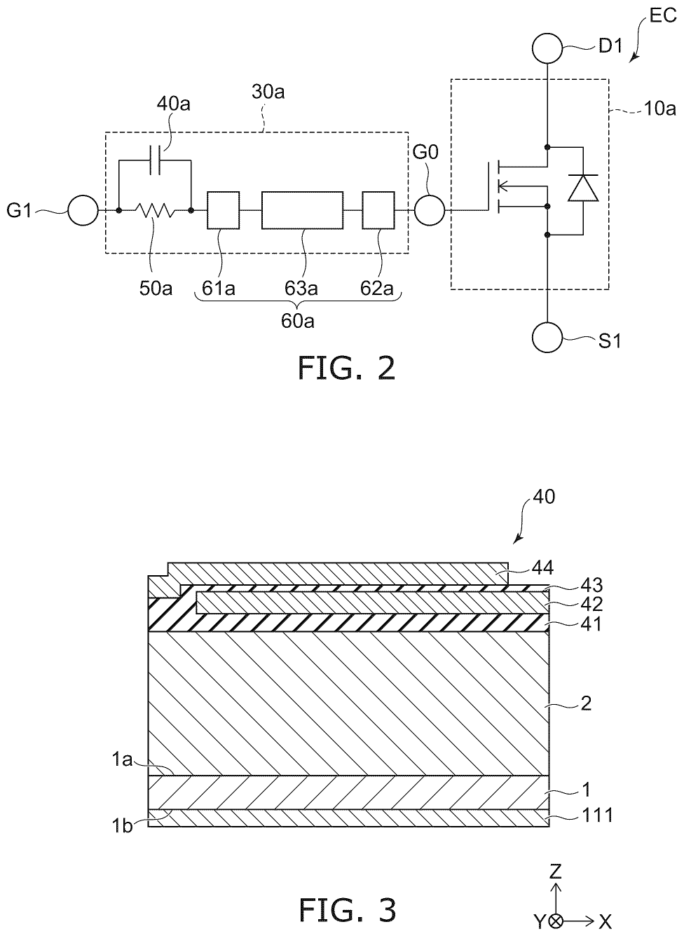

FIG. 2 is a schematic circuit diagram illustrating an equivalent circuit of the semiconductor device according to the first embodiment.

As shown in FIG. 2, an equivalent circuit EC corresponding to the semiconductor device 100 in FIG. 1 includes a transistor section 10a, a gate electrode pad G1, and a gate circuit section 30a.

The gate circuit section 30a is connected between a gate electrode G0 of the transistor section 10a and the gate electrode pad G1. The gate circuit section 30a includes a capacitor 40a, a resistive element 50a, and a gate wiring 60a. The capacitor 40a and the resistive element 50a are connected in parallel. A parallel circuit of the capacitor 40a and the resistive element 50a is connected to the gate wiring 60a in series.

Correspondence relationships of constituent elements of the semiconductor device 100 in FIG. 1 and the equivalent circuit EC are as follows. Specifically, the transistor section 10a corresponds to the transistor section 10 in FIG. 1, the gate electrode pad G1 corresponds to the gate electrode pad 20 in FIG. 1, and the gate circuit section 30a corresponds to the gate circuit section 30 in FIG. 1. In the gate circuit sections 30 and 30a, the resistive element 50a corresponds to the resistive element 50 in FIG. 1, the capacitor 40a corresponds to the capacitor 40 in FIG. 1, and the gate wiring 60a corresponds to the gate wiring 60 in FIG. 1.

The gate wiring 60a includes impedance elements 61a, 62a, and 63a. The impedance elements 61a, 62a, and 63a are connected in series. The impedance elements 61a, 62a, and 63a have impedance values corresponding to the impedance elements 61a, 62a, and 63a, respectively.

The impedance elements 61a, 62a, and 63a correspond to the wirings 61, 62, and 63 in FIG. 1. The impedance values of the impedance elements 61a, 62a, and 63a correspond to the impedance values of the wirings 61, 62, and 63, respectively.

An impedance value of a wiring is based on a length, a width, and the thickness of the wiring. Specifically, the impedance value of the wiring is smaller as the length of the wiring is shorter. The impedance value of the wiring is smaller as the width of the wiring is larger. The impedance value of the wiring is smaller as the thickness of the wiring is larger. That is, the impedance values of the wirings 61, 62, and 63 can be made small by shortening the length of the wirings 61, 62, and 63, by widening the width, and by increasing the thickness.

In the semiconductor device 100 according to the embodiment, the capacitor 40 is connected between the gate electrode pad 20 and the gate electrode of the transistor section 10. The capacitor 40 is connected to the gate electrode of the transistor section 10 in series, and thus a capacitance value seen from the gate electrode pad 20 is an approximately combined capacitance value of a capacitance value of the capacitor 40 and input capacitance value of the transistor section 10.

For example, in a case where the capacitance value of the capacitor 40 is set to be approximately the same as an input capacitance value of the transistor section 10, the combined capacitance value becomes approximately the half of the input capacitance value. In a case where the transistor section 10 is driven with the same impedance as in a case where the capacitor 40 is not connected, a voltage of the gate electrode can be raised to a gate threshold value and can be lowered from the gate threshold value for time that is approximately the half of time in a case where the capacitor 40 is not connected.

A switching speed of the transistor section 10 can be increased by connecting the capacitor 40 having a sufficient capacitance value to the gate electrode of the transistor section 10 in series. Note that, the resistive element 50 that is connected to the capacitor 40 in parallel has a function of suppressing a surge voltage by adjusting the switching speed after the capacitance of the capacitor 40 is charged and discharged. The resistive element 50 has a resistance value, for example, from approximately several 22 to approximately 100Ω.

In this manner, in a case where the capacitor 40 is connected to the gate electrode of the transistor section 10 in series, and the switching speed of the transistor section 10 is increased, in an operation of the semiconductor device 100 according to the embodiment in which charging and discharging of the capacitor 40 is completed during gate driving, when a gate voltage passes a threshold value due to a rapid variation in a charging and discharging current and parasitic inductance of a gate current path, false-OFF or false-ON occurs, and a switching loss increases.

The false-ON or false-OFF operation may cause ringing of a gate current or a main circuit, and thus there is a concern about an increase in noise or element destruction.

In the semiconductor device 100 according to the embodiment, the capacitor 40 and the resistive element 50 are provided on the same semiconductor substrate 1 as in the transistor section 10 and the gate electrode pad 20. Furthermore, the capacitor 40 and the gate electrode pad 20 are disposed adjacent to each other, and the capacitor 40 and the transistor section 10 are disposed contiguously each other as much as possible to reduce the inductance value of the gate wiring 60. In addition, the inductance value of the gate connection wire 102c that electrically connects the gate electrode pad 20 and the gate terminal 101c within the casing 101 is suppressed to be small. According to this, a resonance frequency on the gate side of the transistor section 10 is made to be sufficiently high, thereby suppressing vibration on the gate side due to resonance.

In this manner, in the semiconductor device 100, even when the capacitor 40 is connected to the gate electrode in series, vibration on the gate side is suppressed, and thus an increase in the surge voltage due to occurrence of the ringing on a drain side can be prevented. Therefore, it is possible to reduce the switching loss while increasing the switching speed of the transistor section 10.

FIG. 3 is a schematic cross-sectional view taken along line AA in FIG. 1.

A configuration of the capacitor 40 is shown in FIG. 3.

Hereinafter, description will be made on the assumption that the transistor section 10 is an n-channel MOSFET. When an n-type impurity and a p-type impurity are replaced with each other, the transistor section 10 can be made into a p-channel MOSFET.

As shown in FIG. 3, the capacitor 40 includes a first capacitor electrode 42, a dielectric film 43, and a second capacitor electrode 44. The capacitor 40 is provided on an n-type drift layer 2 through an insulating layer 41. The insulating layer 41 contains, for example, an Si oxide or an Si nitride. The n-type drift layer 2 is provided on the semiconductor substrate 1. The semiconductor substrate 1 contains an n-type impurity. An impurity concentration of the n-type drift layer 2 is lower than an impurity concentration of the semiconductor substrate 1. The semiconductor substrate 1 is provided on the drain electrode 111.

The first capacitor electrode 42 is provided on the insulating layer 41. The first capacitor electrode 42 contains, for example, polycrystalline Si. The first capacitor electrode 42 may contain a metal material such as Al, Cu, and Ti.

The dielectric film 43 is provided on the first capacitor electrode 42. The dielectric film 43 is also provided on the insulating layer 41. The dielectric film 43 contains, for example, an Si oxide or an Si nitride. The dielectric film 43 may be an insulating material having high permittivity such as an Hf oxide. Materials for forming the insulating layer 41 and the dielectric film 43 may be the same as each other or may be different from each other.

The second capacitor electrode 44 is provided on the dielectric film 43. The second capacitor electrode 44 is provided on the first capacitor electrode 42 through the dielectric film 43. The second capacitor electrode 44 contains, for example, polycrystalline Si. The second capacitor electrode 44 may contain a metal material such as Al, Cu, and Ti. Materials for forming the first capacitor electrode 42 and the second capacitor electrode 44 may be the same as each other or may be different from each other.

The first capacitor electrode 42 is connected to, for example, the wiring 61 shown in FIG. 1. The second capacitor electrode 44 is connected to, for example, the wiring 62 shown in FIG. 1. The first capacitor electrode 42 and the wiring 61 may be formed from the same material. The second capacitor electrode 44 and the wiring 62 may be formed from the same material. When forming the capacitor electrode and the wiring with the same material, it is possible to simplify a process of forming the members.

The capacitance value of the capacitor 40 can be increased by reducing the thickness of the dielectric film 43 between the first capacitor electrode 42 and the second capacitor electrode 44. The capacitance value of the capacitor 40 can be increased by setting dielectric film 43 to a material having high permittivity.

FIG. 4 is a schematic cross-sectional view taken along line BB in FIG. 1.

A configuration of the transistor section 10 is shown in FIG. 4.

As shown in FIG. 4, the transistor section 10 includes the n-type drift layer 2, a p-type base layer 3, an n-type source layer 4, the gate electrode 5, and a gate insulating film 6.

The n-type drift layer 2 is provided on the drain electrode 111. The p-type base layer 3 is provided on the n-type drift layer 2. The n-type source layer 4 is selectively provided on the p-type base layer 3.

The gate electrode 5 faces the p-type base layer 3 through the gate insulating film 6. The gate electrode 5 faces the n-type source layer 4 through the gate insulating film 6. The gate electrode 5 faces a part of the n-type drift layer 2 through the gate insulating film 6. Multiple gate electrodes 5 are provided and arranged, for example, in the X-direction. Although not shown in the drawings, multiple gate electrodes 5 are also arranged, for example, in the Y-direction. The gate electrodes 5 are arranged, for example, in a matrix shape in plan view.

Each of the gate electrodes 5 contains, for example, polycrystalline Si. The gate insulating film 6 contains, for example, an Si oxide.

In the specific example in FIG. 4, the gate electrode 5 has, for example, a cylindrical shape extending in the Z-direction, and the cylindrical shape is, for example, a circular shape, an elliptical shape, a square shape, or a hexagonal shape in plan view. A field plate structure 7 is provided inside the cylindrical shape formed by the gate electrode 5. The field plate structure 7 includes a field plate electrode (conductive body) 7a and an insulating film 7b1.

In the field plate structure 7, the field plate electrode 7a faces the gate electrode 5 through an insulating film (second insulating film) 7b2. The field plate electrode 7a extends to a downward side from the gate electrode 5, and the insulating film (first insulating film) 7b1 surrounds the periphery of the field plate electrode 7a. On a downward side of the gate electrode 5, the field plate electrode 7a faces the n-type drift layer 2 through the insulating film 7b1.

The field plate electrode 7a contains, for example, polycrystalline Si. The field plate electrode 7a can be formed from the same material as in the gate electrode 5. The insulating films 7b1 and 7b2 contain, for example, an Si oxide.

An interlayer insulating film 8 is provided on the gate electrode 5 and on the field plate electrode 7a. The interlayer insulating film 8 covers a part of the n-type source layer 4.

The source electrode 112 is provided on the interlayer insulating film 8. The source electrode 112 is provided on the n-type source layer 4 and the p-type base layer 3 which are not covered by the interlayer insulating film 8, and is electrically connected to the n-type source layer 4 and the p-type base layer 3.

Although not shown in the drawings, the resistive element 50 is provided, for example, on the n-type drift layer 2 through an insulating layer, and contains, for example, polycrystalline Si containing an n-type or p-type impurity. The resistive element 50 may be, for example, a p-type semiconductor layer provided on the n-type drift layer 2. The resistive element 50 may be, for example, a film that is provided on the n-type drift layer 2 through an insulating layer and contains, for example, tungsten, aluminum, nickel, titanium, or the like. The resistive element 50 may be, for example, a high-resistance film that is provided on the n-type drift layer 2 through an insulating layer, and uses, for example, SiN, semi-insulating polycrystalline silicon (SIPOS), or the like.

In addition to the above description, the following variation is applicable to the capacitor.

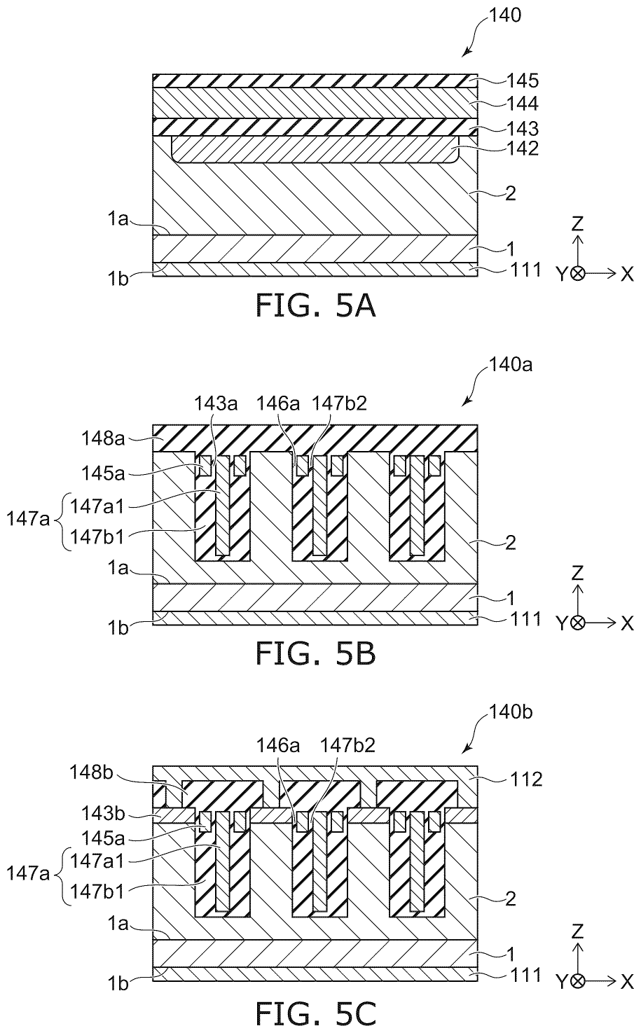

FIG. 5A to FIG. 5C are schematic cross-sectional views illustrating a capacitor that is a part of semiconductor devices according to variations of the first embodiment.

As shown in FIG. 5A, a capacitor 140 of a variation includes a first capacitor electrode 142, a dielectric film 143, and a second capacitor electrode 144.

The first capacitor electrode 142 is provided on the n-type drift layer 2. The first capacitor electrode 142 is a semiconductor layer containing a p-type impurity. An impurity concentration of the first capacitor electrode 142 is approximately the same as, for example, an impurity concentration of the p-type base layer 3 of the transistor section 10 shown in FIG. 4.

The dielectric film 143 is provided on the first capacitor electrode 142. In a specific example in FIG. 5A, the first capacitor electrode 142 is selectively provided on the n-type drift layer 2, and the dielectric film 143 is provided also on the n-type drift layer 2. The dielectric film 143 contains, for example, an Si oxide or an Si nitride. The dielectric film 143 may be an insulating material such as an Hf oxide having high permittivity.

The second capacitor electrode 144 is provided on the dielectric film 143. The second capacitor electrode 144 is provided on the first capacitor electrode 142 through the dielectric film 143. The second capacitor electrode 44 contains, for example, polycrystalline Si. The first capacitor electrode 142 may be a metal material such as Al, Cu, and Ti.

In the specific example in FIG. 5A, an insulating layer 145 is provided on the second capacitor electrode 144.

In the capacitor 140 of the variation shown in FIG. 5A, since the first capacitor electrode 142 is set as a semiconductor layer containing a p-type impurity, the first capacitor electrode 142 can be formed simultaneously with the p-type base layer 3 of the transistor section 10 shown in FIG. 4.

A capacitor 140a of another variation as shown in FIG. 5B includes a first capacitor electrode 145a, a dielectric film 147b2, and a second capacitor electrode 147a1. The first capacitor electrode 145a faces the n-type drift layer 2 through an insulating film (third insulating film) 146a. The first capacitor electrode 145a has, for example, a cylindrical shape extending in the Z-direction. The cylindrical shape is, for example, a circular shape, an elliptical shape, a square shape, or a hexagonal shape in plan view.

Multiple first capacitor electrodes 145a are provided and are arranged, for example, in the X-direction. Although not shown in the drawing, multiple first capacitor electrodes 145a are also arranged in the Y-direction. The first capacitor electrodes 145a are arranged, for example, in a matrix shape in plan view.

The second capacitor electrode 147a1 is provided to extend in the Z-direction from a front face side of the n-type drift layer 2 at the inside of each of the first capacitor electrodes 145a having a cylindrical shape. The second capacitor electrode 147a1 faces the first capacitor electrode 145a through the dielectric film 147b2.

In the specific example in FIG. 5B, the second capacitor electrode 147a1 is provided to further extend to a downward side as compared with the first capacitor electrode 145a. On a downward side of the first capacitor electrode 145a, an insulating film (fourth insulating film) 147b1 surrounds the periphery of the second capacitor electrode 147a1. The second capacitor electrode 147a1 faces the n-type drift layer 2 through the dielectric film 147b2 on a downward side of the first capacitor electrode 145a.

An interlayer insulating film 148a is provided on the first capacitor electrode 145a, on the dielectric film 147b2, and on the second capacitor electrode 147a1. The interlayer insulating film 148a is also provided on the n-type drift layer 2. The interlayer insulating film 148a contains, for example, an Si oxide or an Si nitride.

The first capacitor electrode 145a contains, for example, polycrystalline Si. The first capacitor electrode 145a can be formed from the same material as in the gate electrode 5. The second capacitor electrode 147a1 contains, for example, polycrystalline Si. The second capacitor electrode 147a1 can be formed from the same material as in the field plate electrode 7a.

In the variation, when the first capacitor electrode 145a is formed from the same material as in the gate electrode 5, the first capacitor electrode 145a can be formed by the same process as in the gate electrode 5. In addition, when the second capacitor electrode 147a1 is formed from the same material as in the field plate electrode 7a, the second capacitor electrode 147a1 can be formed by the same process as in the field plate electrode 7a.

Note that, the second capacitor electrode 147a1 and the insulating film 147b1 constitute the structure 147a, and thus a process of forming the structure 147a can be made common to a process of forming the field plate structure 7.

As shown in FIG. 5C, a capacitor 140b of the variation includes the first capacitor electrode 145a, the dielectric film 147b2, and the second capacitor electrode 147a1. In the variation, the capacitor 140b is different from the capacitor 140a shown in FIG. 5B in that a p-type base layer 143b, an interlayer insulating film 148b, and a source electrode 112 are further provided.

The p-type base layer 143b is provided on the n-type drift layer 2. The first capacitor electrode 145a faces the p-type base layer 143b through the insulating film 146a. The first capacitor electrode 145a faces a part of the n-type drift layer 2 through the insulating film 146a.

The p-type base layer 143b is a semiconductor layer containing a p-type impurity. An impurity concentration of the p-type base layer 143b is approximately the same as, for example, the impurity concentration of the p-type base layer 3 of the transistor section 10 shown in FIG. 4.

The interlayer insulating film 148b is provided on the first capacitor electrode 145a, on the dielectric film 147b2, and on the second capacitor electrode 147a1. The interlayer insulating film 148b is provided at a part on the p-type base layer 143b.

The interlayer insulating film 148b contains, for example, an Si oxide or an Si nitride. The interlayer insulating film 148b can be formed from the same material as in the interlayer insulating film 8 of the transistor section 10 shown in FIG. 4.

The source electrode 112 is provided on the interlayer insulating film 148b. The source electrode 112 is provided on the p-type base layer 143b through a passage provided in the interlayer insulating film 148b, and is electrically connected to the p-type base layer 143b.

In the variation, the p-type base layer 143b and the second capacitor electrode 147a1 are connected to the source electrode 112, and thus the first capacitor electrode 145a faces the p-type base layer 143b at one face of the first capacitor electrode 145a and faces the second capacitor electrode 147a1 at the other face. Accordingly, a capacitance value of the capacitor 140b can be made larger as compared with the capacitor 140a shown in FIG. 5B.

In addition, in the variation, when an impurity concentration of the p-type base layer 143b is made to be the same as the impurity concentration of the p-type base layer 3, the p-type base layers 143b and 3 can be formed by the same process. When the interlayer insulating film 148b is formed from the same material as in the interlayer insulating film 8, the interlayer insulating films 148b and 8 can be formed by the same process.

As shown in the specific examples, the transistor section 10, the capacitor 40, and the resistive element 50 are provided on the n-type drift layer 2 provided on the semiconductor substrate 1. The gate electrode 5 of the transistor section 10 can be electrically connected to the gate electrode pad 20, the capacitor 40, and the resistive element 50 with the gate wiring 60 on the semiconductor device 100.

When the transistor section 10, the gate electrode pad 20, the capacitor 40, and the resistive element 50 are appropriately disposed in plan view, the length of the gate wiring 60 can be sufficiently shortened. Therefore, the inductance value of the gate wiring 60 can be suppressed to be small, vibration in the gate circuit of the transistor section 10 is suppressed, and ringing on the drain side can be prevented from occurring.

An operation and an effect of the semiconductor device 100 according to the embodiment will be described.

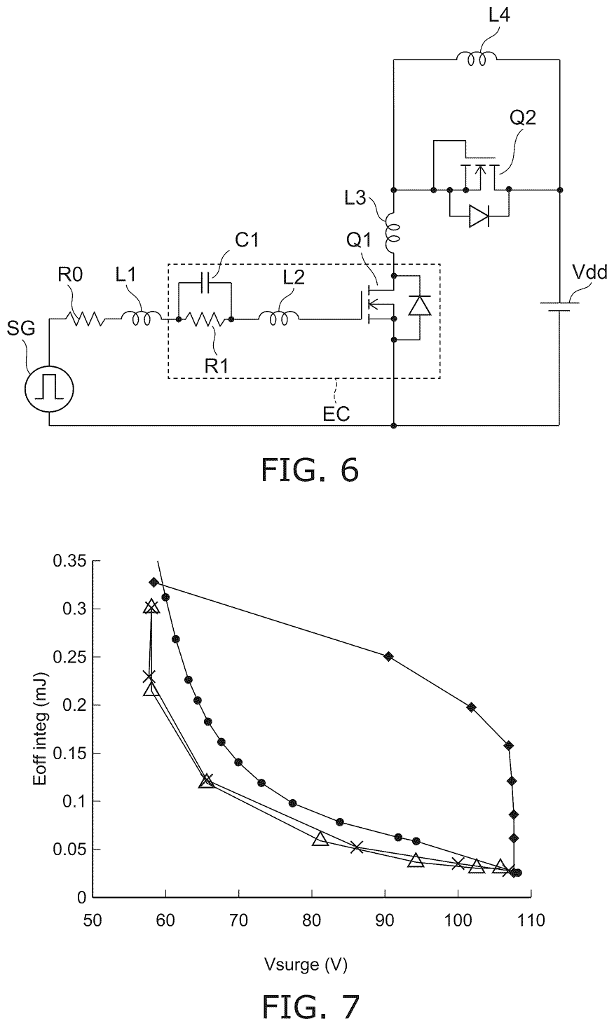

FIG. 6 is a circuit diagram for simulating characteristics in switching of the semiconductor device according to the first embodiment.

FIG. 7 is a graph of a characteristic example in switching in a case where an inductance value from a gate circuit section is set as a parameter in the circuit illustrated in FIG. 6.

An inner side of a broken line in FIG. 6 is the equivalent circuit EC shown in FIG. 2. In FIG. 6, a transistor Q1 corresponds to the transistor section 10 in FIG. 1, a capacitor C1 corresponds to the capacitor 40 in FIG. 1, and a resistive element R1 corresponds to the resistive element 50 in FIG. 1. In addition, in FIG. 6, an inductance value of inductance L2 corresponds to the inductance value of the series circuit of the gate wiring 60 and the gate connection wire 102c in FIG. 1. Inductance L1 represents an inductance value of a wiring between the gate terminal 101c of the semiconductor device 100 and a signal generator SG.

The simulation circuit in FIG. 6 shows a drive circuit that drives an inductive load L4. A transistor Q2 connected to both ends of the inductive load L4 is provided to short-circuit between a gate and a source, and to function as a flywheel diode that clamps a voltage due to counter electromotive force generated when the transistor Q1 is turned off.

Inductance L3 represents inductance of a wiring between a source terminal of the transistor Q1 and the inductive load L4. When the transistor Q1 is turned off, a voltage that is the product of a temporal variation of a current flowing through the inductance L3 and the inductance value of the inductance L3 is superimposed on a power supply voltage Vdd in the form of a surge, and is applied between a drain and a source of the transistor Q1.

A resistor R0 represents output resistance of the signal generator SG. As a resistance value of the resistor R0 is smaller, a current value capable of flowing between the signal generator SG and the equivalent circuit EC can be further increased. A switching speed of the transistor Q1 can be adjusted by adjusting the resistance value of the resistor R0.

In a case where an inductive load is driven by the transistor Q1, as described above, when the transistor Q1 is turned off, a voltage in the form of a surge is superimposed on a power supply voltage. Hereinafter, a maximum peak voltage that is applied between the drain and the source of the transistor Q1 when the transistor Q1 is turned off is defined as a surge voltage Vsurge.

The vertical axis of FIG. 7 represents switching loss Eoff as energy when the transistor Q1 in FIG. 6 is turned off. The horizontal axis of FIG. 7 represents the surge voltage Vsurge applied between the drain and the source of the transistor Q1. In plotting of the graph in FIG. 7, off-time of the transistor Q1 is changed by making the output resistance R0 of the signal generator SG variable.

In FIG. 7, Vsurge and Eoff when a capacitance value of the capacitor C1 is changed are plotted by using an inductance value L of a series circuit of the inductance L1 and inductance L2 as a parameter. In respective plottings, “♦” represents simulation results in a case where L is 15 nH, “x” represents simulation results in a case where L is 8 nH, “Δ” represents simulation results in a case where L is 6 nH. “∘” represents a plot when both ends of the capacitor C1 are short-circuited, and R0 is changed as in a conventional product.

As shown by a plot of “∘” in FIG. 7, the smaller a resistance value on the signal generator SG side, the faster the switching speed in OFF, and the lower the switching loss Eoff. On the other hand, as a temporal variation rate of a current flowing through the inductance L3 on a load side of the transistor Q1 increases, the surge voltage Vsurge increases.

The transistor Q1 is switched at a higher speed as compared with the plot of “∘” by validating the capacitor C1, and then the switching loss Eoff is measured.

In the respective plots of “♦”, “x”, and “Δ”, on the gate side of the transistor Q1, a resonance circuit is formed by the inductance value of the inductance L1 and the inductance L2 of wirings, and a capacitance value on a gate side of the transistor Q1. Due to the resonance circuit, the gate side of the transistor Q1 vibrates, and a drain side of the transistor Q1 also vibrates due to the vibration, and thus ringing occurs. Due to the ringing on the drain side of the transistor Q1, a drain current and a drain-source voltage cross each other many times, and the switching loss Eoff increases.

In FIG. 7, in the plot of “♦” in a case where the inductance value is 15 nH, in a case where the resistance value on an output side of the signal generator SG is made sufficiently small, the surge voltage Vsurge is generated mainly by the inductance L3 on a drain side of the transistor Q1. In the simulation results, a maximum surge voltage Vsurge is approximately 110 V.

In the plot of “♦”, when the resistance value R0 on the signal generator SG side is gradually increased, the surge voltage Vsurge does not decrease too much, and the switching loss Eoff is also larger as compared with the plot of “∘”. The reason for this is because ringing occurs on the drain side of the transistor Q1 in an oscillation circuit formed by the inductance value on the gate side of the transistor Q1, the capacitance value of the capacitor C1, and parasitic capacitance on the gate side of the transistor Q1.

In the plot of “x” in a case where the inductance value is 8 nH, as the resistance value of the resistor R0 on the signal generator SG side is lowered, the surge voltage Vsurge also decreases. In the plot of “x”, in a case of the same surge voltage Vsurge, the switching loss Eoff in OFF is further lowered as compared with the plot of “∘”.

In this manner, when the inductance value on the gate side of the transistor Q1 is made sufficiently small, vibration on the gate side is suppressed, and occurrence of ringing on the drain side can be prevented. When the ringing on the drain side is prevented, high-speed switching of the transistor Q1 can be performed, and switching loss Eoff due to high-speed switching can be reduced.

In the plot of “Δ” in a case where the inductance value is 6 nH, vibration on the gate side of the transistor Q1 is further suppressed. Therefore, ringing on the drain side of the transistor Q1 can also be suppressed, and it is shown that the switching loss Eoff can be reduced.

In this manner, when the capacitor C1 is inserted as a gate circuit, and the inductance value of the wiring on the gate side is suppressed to be small, ringing on the drain side is prevented, and high-speed switching operation of the transistor can be performed, and switching loss can be reduced.

The semiconductor device 100 according to the embodiment is configured on the basis of the simulation results. That is, in the semiconductor device 100, the capacitor 40 and the resistive element 50 constitute a parallel circuit, the gate electrode 5 of the transistor section 10 and the gate electrode pad 20 are electrically connected through the gate wiring 60.

Since the capacitor 40 is connected to gate input capacitance of the transistor section 10 in series, a capacitance value when seen from the gate terminal 101c side decreases. Therefore, since substantial drive capability of a drive-side circuit is improved, the switching speed of the transistor section 10 can be increased.

The transistor section 10, the gate electrode pad 20, the capacitor 40, and the resistive element 50 are appropriately disposed on the same semiconductor substrate 1. Therefore, a parallel circuit of the capacitor 40 and the resistive element 50 electrically connects between the gate electrode 5 of the transistor section 10 and the gate electrode pad 20 at a sufficiently short distance. Therefore, the inductance value of the gate wiring 60 can be suppressed to be sufficiently small. In addition, the inductance value of the gate connection wire 102c can also be made sufficiently small by making the gate connection wire 102c sufficiently short and by providing multiple thick wires.

According to this, even in a case where the transistor section 10 is switched at a high speed by connecting the capacitor 40 between the gate electrode pad 20 and the gate electrode 5 of the transistor section 10, vibration on the gate side can be suppressed, and thus ringing on the drain side is prevented. Since ringing that occurs on the drain side of the transistor section 10 is prevented, the switching loss can be reduced.

For example, when a wiring between a drive circuit for the semiconductor device 100 such as a signal generator, and the gate terminal 101c of the semiconductor device 100 is made sufficiently short and thick, the inductance value of the wiring can be sufficiently reduced to approximate to 0. In a case where the sum of the inductance value of the wiring and the inductance value of the series circuit of the gate connection wire 102c and the gate wiring 60 of the semiconductor device 100 is set to 8 nH or less, the switching loss due to the high-speed switching can be reduced.

### Variations

From the viewpoint of shortening a length of a gate wiring and reducing an inductance value of the wiring, a transistor section, a gate electrode pad, a capacitor, and a resistive element can be appropriately disposed in plan view.

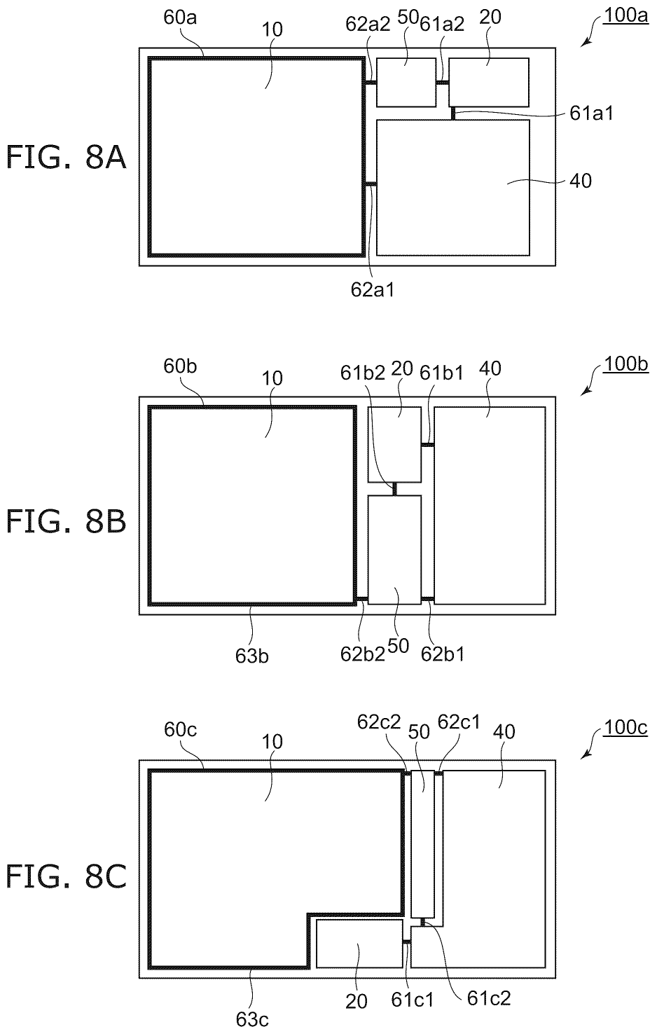

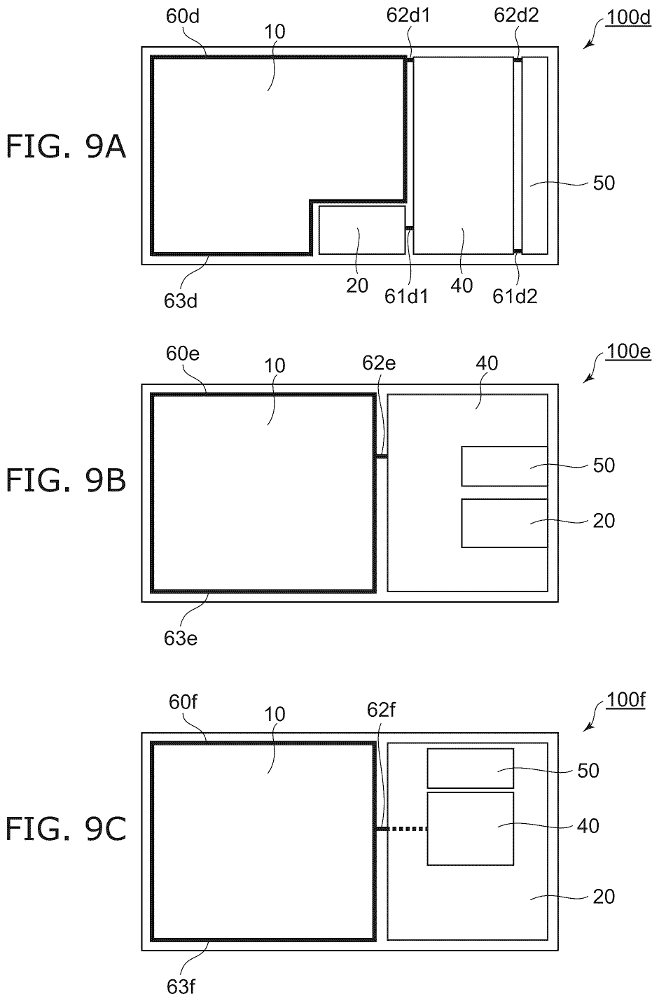

FIG. 8A to FIG. 9C are schematic plan views illustrating a semiconductor device according to a variation of the first embodiment.

As shown in FIG. 8A, in a semiconductor device 100a of the variation, the capacitor 40 is disposed adjacent to the gate electrode pad 20. In addition, the capacitor 40 is disposed adjacent to the transistor section 10. The resistive element 50 is disposed between the transistor section 10 and the gate electrode pad 20, and is disposed adjacent to the transistor section 10 and the gate electrode pad 20. The gate wiring 60a includes wirings 61a1, 61a2, 62a1, and 62a2.

A wiring 63a is provided to surround the outer periphery of the transistor section 10.

The wiring 61a1 is provided between the gate electrode pad 20 and the capacitor 40, and electrically connects the gate electrode pad 20 and the capacitor 40. The wiring 62a1 is provided between the transistor section 10 and the capacitor 40, and electrically connects the wiring 63a and the capacitor 40.

The wiring 61a2 is provided between the gate electrode pad 20 and one end of the resistive element 50, and electrically connects the gate electrode pad 20 and the one end of the resistive element 50. The wiring 62a2 is provided between the transistor section 10 and the other end of the resistive element 50, and electrically connects the wiring 63a and the other end of the resistive element 50.

When the gate electrode pad 20 and the capacitor 40 are disposed adjacent to each other, the wiring 61a1 can electrically connect the gate electrode pad 20 and the capacitor 40 with a sufficiently short length. When the transistor section 10 and the capacitor 40 are disposed adjacent to each other, the wiring 62a1 can electrically connect the wiring 63a and the capacitor 40 with a sufficient short length. When the length of the wirings 61a1 and 62a1 is sufficiently shortened, an inductance value of the wirings 61a1 and 62a1 can be reduced.

When the gate electrode pad 20 and the resistive element 50 are disposed adjacent to each other, the wiring 61a2 can electrically connect the gate electrode pad 20 and the one end of the resistive element 50 with a sufficiently short length. When the transistor section 10 and the resistive element 50 are disposed adjacent to each other, the wiring 62a2 can electrically connect the wiring 63a and the other end of the resistive element 50 with a sufficiently short length. When the length of the wirings 61a2 and 62a2 is made sufficiently short, the inductance value of the wirings 61a2 and 62a2 can be reduced.

An inductance value due to a wiring can be reduced by shortening the length of the wiring, and can also be reduced by widening the width of the wiring. For example, in the semiconductor device 100a, the parasitic inductance of the wirings 61a1 and 62a2 can be reduced by sufficiently widening the width of the wirings 61a1 and 62a2 in correspondence with the shape of the gate electrode pad 20. In addition, the inductance value of the wirings 62a1 and 62a2 can be reduced by sufficiently widening the width of the wirings 62a1 and 62a2 in correspondence with the shape of the transistor section 10.

As shown in FIG. 8B, in a semiconductor device 100b according to a variation, the gate electrode pad 20 is disposed between the transistor section 10 and the capacitor 40, and is disposed adjacent to the transistor section 10 and the capacitor 40. The resistive element 50 is disposed between the gate electrode pad 20, the transistor section 10, and the capacitor 40, and is disposed adjacent to the transistor section 10 and the capacitor 40. In addition, the gate electrode pad 20 and the resistive element 50 are disposed adjacent to each other. The gate wiring 60b includes a wiring 61b1, 61b2, 62b1, 62b2, and 63b.

The wiring 63b is provided to surround the outer periphery of the transistor section 10.

The wiring 61b1 is provided between the gate electrode pad 20 and the capacitor 40, and electrically connects the gate electrode pad 20 and the capacitor 40. The wiring 62b1 is provided between the capacitor 40 and the resistive element 50, and electrically connects the capacitor 40 and one end of the resistive element 50.

The wiring 61b2 is provided between the gate electrode pad 20 and the resistive element 50, and electrically connects the gate electrode pad 20 and the other end of the resistive element 50. The wiring 62b2 is provided between the transistor section 10 and the resistive element 50, and electrically connects the wiring 63b and the one end of the resistive element 50.

When the gate electrode pad 20 and the capacitor 40 are disposed adjacent to each other, the wiring 61b1 can connect the gate electrode pad 20 and the capacitor 40 with a sufficiently short length. When the capacitor 40 and the resistive element 50 are disposed adjacent to each other, the wiring 62b1 can connect the capacitor 40 and the resistive element 50 with a sufficiently short length. When the length of the wirings 61b1 and 62b1 is sufficiently shortened, an inductance value of the wirings 61b1 and 62b1 can be reduced.

When the gate electrode pad 20 and the resistive element 50 are disposed adjacent to each other, the wiring 61b2 can connect the gate electrode pad 20 and the resistive element 50 with a sufficiently short length. When the transistor section 10 and the resistive element 50 are disposed adjacent to each other, the wiring 62b2 can connect the wiring 63b and the resistive element 50 with a sufficiently short length. When the length of the wirings 61b2 and 62b2 is made sufficiently short, the inductance value of the wirings 61b2 and 62b2 can be reduced.

For example, the width of each of the wirings 61b1 and 61b2 is sufficiently widened in correspondence with the shape of the gate electrode pad 20, the inductance value of the wirings 61b1 and 61b2 can be reduced.

As shown in FIG. 8C, in a semiconductor device 100c of a variation, the gate electrode pad 20 is disposed between the transistor section 10 and the capacitor 40, and is disposed adjacent to the transistor section 10 and the capacitor 40. The resistive element 50 is disposed between the transistor section 10 and the capacitor 40, and is disposed adjacent to the transistor section 10 and the capacitor 40. In addition, the resistive element 50 is not adjacent to the gate electrode pad 20. A gate wiring 60c includes wirings 61c1, 61c2, 62c1, 62c2, and 63c.

The wiring 63c is provided to surround the outer periphery of the transistor section 10.

The wiring 61c1 is provided between the gate electrode pad 20 and the capacitor 40, and electrically connects the gate electrode pad 20 and the capacitor 40. The wiring 62c1 is provided between the capacitor 40 and the resistive element 50, and electrically connects the capacitor 40 and one end of the resistive element 50.

The wiring 61c2 is provided between the capacitor 40 and the resistive element 50, and electrically connects the capacitor 40 and the other end of the resistive element 50. The wiring 62c2 is provided between the transistor section 10 and the resistive element 50, and electrically connects the wiring 63c and the one end of the resistive element 50. In the variation, since the resistive element 50 is not adjacent to the gate electrode pad 20, the resistive element 50 is electrically connected to the gate electrode pad 20 through the wiring 61c2, the capacitor 40, and the wiring 61c1. In addition, since the capacitor 40 is not adjacent to the transistor section 10, the capacitor 40 is electrically connected to the wiring 63c through the wiring 62c1, the resistive element 50, and the wiring 62c2.

When the gate electrode pad 20 and the capacitor 40 are disposed adjacent to each other, the wiring 61c1 can connect the gate electrode pad 20 and the capacitor 40 with a sufficiently short length. When the capacitor 40 and the resistive element 50 are disposed adjacent to each other, the wiring 62c1 can connect the capacitor 40 and the resistive element 50 with a sufficiently short length. When the length of the wirings 61c1 and 62c1 is sufficiently shortened, the inductance value of the wirings 61c1 and 62c2 can be reduced.

When the capacitor 40 and the resistive element 50 are disposed adjacent to each other, the wiring 61c2 can connect the capacitor 40 and the resistive element 50 with a sufficiently short length. When the transistor section 10 and the resistive element 50 are disposed adjacent to each other, the wiring 62c2 can connect the wiring 63c and the resistive element 50 with a sufficiently short length. When the length of the wirings 61c2 and 62c2 is sufficiently shortened, the inductance value of the wirings 61c2 and 62c2 can be reduced.

For example, when the width of the wirings 61c1 and 61c2 is sufficiently widened in correspondence with the shape of the gate electrode pad 20, the inductance value of the wirings 61c1 and 61c2 can be reduced.

In the variation, since the capacitor 40 is connected to the wiring 63c through the wiring 62c1, the resistive element 50, and the wiring 62c2, it is favorable to set the length of the resistive element 50 between the transistor section 10 and the capacitor 40 to a short length to reduce an inductance value due to the resistive element 50.

As shown in FIG. 9A, in a semiconductor device 100d of a variation, the gate electrode pad 20 is disposed between the transistor section 10 and the capacitor 40, and is disposed adjacent to the transistor section 10 and the capacitor 40. A part of the capacitor 40 is disposed between the transistor section 10 and the resistive element 50, and is disposed adjacent to the transistor section 10 and the resistive element 50. The remaining portion of the capacitor 40 is disposed between the gate electrode pad 20 and the resistive element 50, and is disposed adjacent to the gate electrode pad 20 and the resistive element 50. A gate wiring 60d includes wirings 61d1, 61d2, 62d1, 62d2, and 63d.

The wiring 63d is provided to surround the outer periphery of the transistor section 10.

The wiring 61d1 is provided between the gate electrode pad 20 and the capacitor 40, and electrically connects the gate electrode pad 20 and the capacitor 40. The wiring 62d1 is provided between the transistor section 10 and the capacitor 40, and electrically connects the wiring 63d and the capacitor 40.

The wiring 61d2 is provided between the capacitor 40 and the resistive element 50, and electrically connects the capacitor 40 and one end of the resistive element 50. The wiring 62d2 is provided between the capacitor 40 and the resistive element 50, and electrically connects the capacitor 40 and the other end of the resistive element 50. In the variation, since the resistive element 50 is not adjacent to the gate electrode pad 20, the one end of the resistive element 50 is electrically connected to the gate electrode pad 20 through the wiring 61d2, the capacitor 40, and the wiring 61d1. In addition, since the resistive element 50 is not adjacent to the transistor section 10, the other end of the resistive element 50 is electrically connected to the wiring 63d through the wiring 62d2, the capacitor 40, and the wiring 62d1.

When the gate electrode pad 20 and the capacitor 40 are disposed adjacent to each other, the wiring 61d1 can electrically connect the gate electrode pad 20 and the capacitor 40 with a sufficiently short length. When the transistor section 10 and the capacitor 40 are disposed adjacent to each other, the wiring 62d1 can electrically connect the wiring 63d and the capacitor 40 with a sufficiently short length. When the length of the wirings 61d1 and 62d1 is sufficiently shortened, the inductance value of the wirings 61d1 and 62d1 can be reduced.

When the capacitor 40 and the resistive element 50 are disposed adjacent to each other, the wirings 61d2 and 62d2 can connect the capacitor 40 and the resistive element 50 with a sufficiently short length. When the length of the wirings 61d2 and 62d2 is sufficiently shortened, the inductance value of the wirings 61d2 and 62d2 can be reduced.

For example, when the width of the wiring 61d1 is sufficiently widened in correspondence with the shape of the gate electrode pad 20, the inductance value of the wiring can be reduced. In addition, when the width of the wiring 62d2 is sufficiently widened in correspondence with the shape of the transistor section 10 and the capacitor 40, the inductance value can be reduced.

In the variation, the one end of the resistive element 50 is electrically connected to the gate electrode pad 20 through one capacitor electrode of the capacitor 40. In addition, the other end of the resistive element 50 is electrically connected to the wiring 63d through the other electrode of the capacitor 40. As described above with reference to FIG. 3, and FIG. 5A to FIG. 5C, the width of the two capacitor electrodes is sufficiently wide, and the inductance value of the capacitor electrodes is sufficiently small. According to this, the inductance value between the resistive element 50 and the gate electrode pad 20 can be made sufficiently small, and the inductance value between the resistive element 50 and the wiring 63d can also be made sufficiently small.

As shown in FIG. 9B, in a semiconductor device 100e of a variation, the transistor section 10 and the capacitor 40 are disposed adjacent to each other. The gate electrode pad 20 and the resistive element 50 are provided on the capacitor 40. A gate wiring 60e includes wirings 62e and 63e.

The wiring 62e is provided between the transistor section 10 and the capacitor 40, and electrically connects the wiring 63e and the capacitor 40. When the transistor section 10 and the capacitor 40 are disposed adjacent to each other, the wiring 62e can electrically connect the wiring 63e and the capacitor 40 with a sufficiently short length. When the length of the wiring 62e is sufficiently shortened, the inductance value of the wiring 62e can be made sufficiently small. The inductance value of the wiring 62e can be made sufficiently small by sufficiently widening the width of the wiring 62e in correspondence with the shape of the transistor section 10.

Electrical connection between the gate electrode pad 20 and the capacitor 40 is performed by connecting the gate electrode pad to one capacitor electrode of the capacitor 40 below the gate electrode pad 20. In addition, electrical connection between the capacitor 40 and the resistive element 50 is performed by connecting one end of the resistive element 50 to the one capacitor electrode of the capacitor 40 and by connecting the other end of the resistive element 50 to the other capacitor electrode of the capacitor 40 below the resistive element 50. According to these, the inductance value of the connection between the gate electrode pad 20 and the capacitor 40 can be made sufficiently small, and the inductance value of the connection between the capacitor 40 and the resistive element 50 can be made sufficiently small.

As shown in FIG. 9C, in a semiconductor device 100f of a variation, the transistor section 10 and the gate electrode pad 20 are disposed adjacent to each other. The capacitor 40 and the resistive element 50 are disposed in parallel. The gate electrode pad 20 surrounds a parallel arrangement of the capacitor 40 and the resistive element 50. A gate wiring 60f includes wirings 62f and 63f.

The wiring 63f is provided to surround the outer periphery of the transistor section.

The wiring 62f is provided between the transistor section 10 and the capacitor 40, and electrically connects the wiring 63f and one capacitor electrode of the capacitor 40. Note that, the gate electrode pad 20 is provided on the wiring 62f through an insulating layer, and the wiring 62f and the gate electrode pad 20 are electrically isolated from each other.

The resistive element 50 is electrically connected to the one capacitor electrode of the capacitor 40 at one end of the resistive element 50, and is electrically connected to the other capacitor electrode of the capacitor 40 at the other end of the resistive element 50. The other capacitor electrode of the capacitor 40 is connected to the gate electrode pad 20 below the gate electrode pad 20.

In the variation, the other capacitor electrode of the capacitor 40 is made sufficiently wide, the gate electrode pad 20 is provided on the sufficiently wide capacitor electrode, and electrical connection between the capacitor electrode and the gate electrode pad 20 is established. According to this, the inductance value of the connection between the gate electrode pad 20 and the capacitor 40 can be made sufficiently small.

In this manner, even in a case where the capacitor 40 is provided to increase the switching speed of the transistor section 10, the inductance value based on mutual connection can be made sufficiently small. Therefore, gate vibration due to capacitance of the capacitor 40, parasitic capacitance of the transistor section 10, and an inductance value on the gate side of the transistor section 10 is suppressed, and occurrence of ringing on the drain side can be prevented. When the ringing on the drain side is prevented, a switching loss can be reduced.

### Second Embodiment

In the embodiment, a capacitor and a resistive element which are formed by a manufacturing process different from that of a transistor section instead of a capacitor and a resistive element formed by the same semiconductor manufacturing process as that of the transistor section.

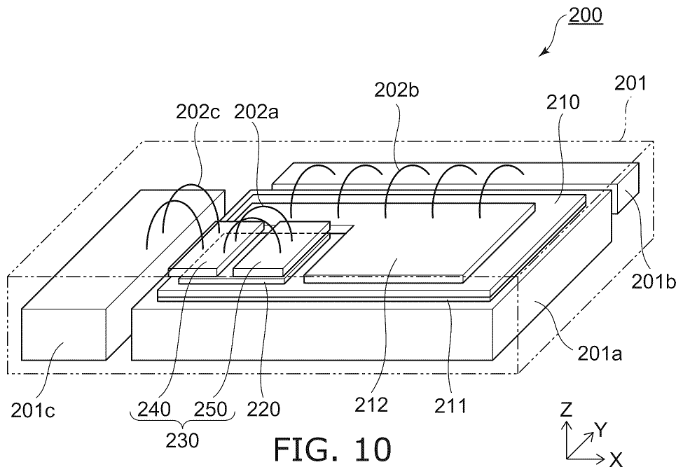

FIG. 10 is a schematic perspective view illustrating a semiconductor device according to a second embodiment.

As shown in FIG. 10, a semiconductor device 200 according to the embodiment includes a transistor section 210 and a gate circuit section 230. The transistor section 210 includes a drain electrode 211, a source electrode 212, and a gate electrode pad 220. The gate circuit section 230 includes a capacitor 240 and a resistive element 250.

In a specific example in FIG. 10, the transistor section 210 is provided on a conductive mount bed 201a. A rear face of the transistor section 210 is electrically connected to the mount bed 201a through a joining member such as solder. The mount bed 201a functions as a drain terminal of the semiconductor device 200. A conductive source terminal 201b and a conductive gate terminal 201c are disposed adjacent to the mount bed 201a. A source connection wire 202b is provided between the source terminal 201b and the source electrode 212 of the transistor section 210, and electrically connects the source terminal 201b and the source electrode 212. A gate connection wire 202c is disposed between the gate terminal 201c and the gate circuit section 230, and electrically connects the gate terminal 201c and the gate circuit section 230.

The mount bed 201a on which the gate circuit section 230 and the transistor section 210 are mounted, the source terminal 201b, the source connection wire 202b, the gate terminal 201c, and the gate connection wire 202c are accommodated in a casing 201. The casing 201 is formed from, for example, an epoxy resin or the like. In FIG. 10, the casing 201 is shown by a two-dot chain line to clearly illustrate the gate circuit section 230, the transistor section 210, the mount bed 201a, the source terminal 201b, the source connection wire 202b, the gate terminal 201c, and the gate connection wire 202c.

In the transistor section 210, the source electrode 212 and the gate electrode pad 220 are provided on a face opposite to a face connected to the mount bed 201a. The source electrode 212 and the gate electrode pad 220 are electrically isolated from each other. A configuration of the transistor section 210 can be made similar to the specific example described with reference to FIG. 4.

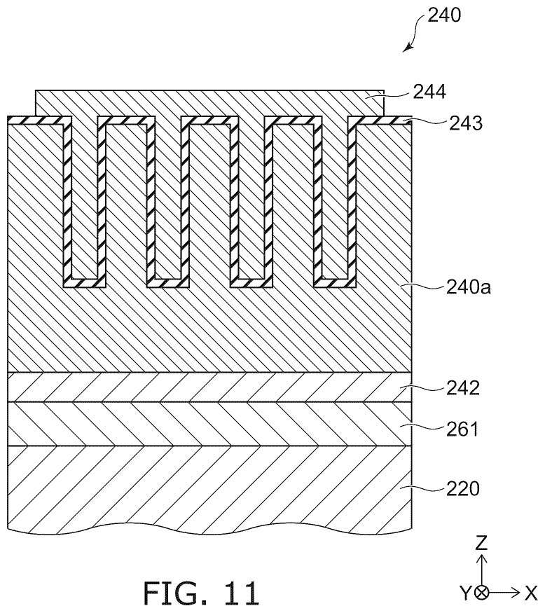

FIG. 11 is a schematic cross-sectional view of a capacitor that is a part of the semiconductor device in FIG. 10.

As shown in FIG. 11, the capacitor 240 includes a first capacitor electrode 240a, a dielectric film 243, and a second capacitor electrode 244. The capacitor 240 is disposed on the gate electrode pad 220 through a joining member 261 such as solder. The first capacitor electrode 240a is provided on a conductive layer 242. Multiple trenches are formed in the first capacitor electrode 240a, and the dielectric film 243 is provided on a wall face of each of the multiple trenches. The second capacitor electrode 244 is provided on the first capacitor electrode 240a through the dielectric film 243.

The capacitor 240 is formed by a manufacturing process different from that of the transistor section 210, and a capacitance value per unit area can be made sufficiently large. The capacitor 240 is, for example, a silicon capacitor. In the silicon capacitor, a fine trench and the like can be formed by a manufacturing process different from that of the transistor section 210, capacitance can be made sufficiently large.

In the silicon capacitor, the first capacitor electrode 240a contains, for example, Si containing an n-type impurity. The dielectric film 243 contains, for example, an Si oxide. The second capacitor electrode 244 contains, for example, polycrystalline Si containing a p-type impurity. The conductive layer 242 contains, for example, a metal that is ohmic-connected to the first capacitor electrode 240a.

In the capacitor 240, the thickness of the first capacitor electrode 240a and the conductive layer 242 is sufficiently small, and an inductance value thereof can be set to approximately 0. In addition, the thickness of the joining member 261 between the first capacitor electrode 240a and the gate electrode pad 220 can be made sufficiently small to approximate an inductance value to 0. Therefore, in the semiconductor device 200 according to the embodiment, among gate wirings, an inductance value of a wiring between the gate electrode pad 220 and the gate circuit section 230 can be set to approximately 0.

The resistive element 250 is formed by a manufacturing process different from that of the transistor section 210. The resistive element 250 is realized, for example, by introducing an n-type impurity with a low concentration into an Si substrate to obtain desired sheet resistance, and by processing the thickness to obtain a desired resistance value.

In the resistive element 250, one electrode is formed on one face, and the other electrode is formed on the other face. Therefore, the one electrode can be electrically connected to the gate electrode pad 220 by disposing the one electrode to face a front face of the gate electrode pad 220 and by connecting the one electrode to the front face. Since connection between the electrode of the resistive element 250 and the gate electrode pad 220 is face-to-face connection, an inductance value can be made sufficiently small.

The capacitor 240 and the resistive element 250 are connected to each other by a mutual connection wire 202a. The mutual connection wire 202a electrically connects the other capacitor electrode of the capacitor 240 and the other electrode of the resistive element 250.

In this manner, the capacitor 240 and the resistive element 250 are connected in parallel, and one end of a parallel circuit of the capacitor 240 and the resistive element 250 is electrically connected to the gate electrode pad 220.

An effect of the semiconductor device 200 according to the embodiment will be described.

The semiconductor device 200 according to the embodiment and variations has a similar effect as in the semiconductor device 100 shown in FIG. 1, and has the following effects other than the effect. That is, in the semiconductor device 200, the gate circuit section 230 is manufactured by using a manufacturing process different from that of the transistor section 210, and is stacked on the gate electrode pad 220 of the transistor section 210 to be electrically connected thereto. A size of the gate circuit section 230 in plan view is set to a size that is approximately equal to or not more than a size of the gate electrode pad 220 in plan view, and thus a size of the semiconductor device 200 in plan view does not exceed the size of the transistor section 210. Accordingly, it is possible to realize the semiconductor device 200 with a small size at low cost.

### Variations

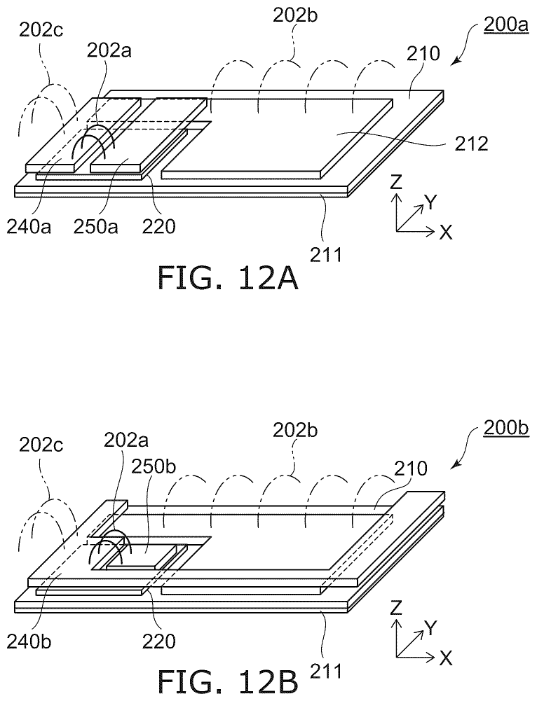

FIG. 12A and FIG. 12B are schematic perspective views illustrating semiconductor devices according to variations of the second embodiment.

In FIG. 12A and FIG. 12B, the mount bed 201a, the source terminal 201b, the gate terminal 201c, and the casing 201 in FIG. 10 are omitted to avoid complication of illustration. In addition, the source terminal 201b and the gate terminal 201c are omitted in the drawings, and the source connection wire 202b and the gate connection wire 202c are shown by a two-dot chain line.

As shown in FIG. 12A, in a semiconductor device 200a of the variation, configurations of a capacitor 240a and a resistive element 250a are different from the case of FIG. 10. The other configurations are the same as in FIG. 10, and the same reference numeral will be given to the same constituent element, and detailed description will be appropriately omitted.

A size of the capacitor 240a in plan view is larger as compared with the example in FIG. 10 so as to obtain a sufficiently large capacitance value. In addition, a size of the resistive element 250a in plan view is larger as compared with the example in FIG. 10 so as to obtain a sufficiently low DC resistance value.

The capacitor 240a and the resistive element 250a cover the gate electrode pad 220 in plan view, and cover a part of the source electrode 212 adjacent to the gate electrode pad 220. Although not shown in the drawing, an insulating layer is provided between the capacitor 240a and the source electrode 212 overlapping the capacitor 240a, and one capacitor electrode of the capacitor 240a and the source electrode 212 are electrically isolated from each other. In addition, an insulating layer is provided between the resistive element 250a and the source electrode 212 overlapping the resistive element 250a, and one electrode of the resistive element 250 and the source electrode 212 are electrically isolated from each other.

As shown in FIG. 12B, in a semiconductor device 200b of the variation, configurations of a capacitor 240b and a resistive element 250b are different from the case of FIG. 10. The other configurations are the same as the case of FIG. 10, and thus the same reference numeral will be given to the same constituent element, and detailed description will be appropriately omitted.

In the capacitor 240b, a size in plan view is larger as compared with the example shown in FIG. 12A so as to obtain a larger capacitance value. On the other hand, in the resistive element 250b, a size in plan view is smaller as compared with the example shown in FIG. 12A.

The capacitor 240b and the resistive element 250b cover the gate electrode pad 220 in plan view. Among these, the capacitor 240b overlaps an outer edge region including three sides of the outer periphery of the transistor section 210 in plan view. The outer edge including the three sides of the outer periphery of the transistor section 210 in plan view is an outer edge other than one outer edge to which the source connection wire 202b is connected. The capacitor 240b may overlap an outer edge of the source electrode 212. Although not shown in the drawing, an insulating layer is provided between the capacitor 240b and the transistor section 210 overlapping the capacitor 240b, and one capacitor electrode of the capacitor 240b and the outer edge of the transistor section 210 are electrically isolated from each other.

In this manner, in the capacitors 240a and 240b, since the shape in plan view can be set to an arbitrary shape, a sufficiently large area can be secured. Therefore, in the semiconductor devices 200a and 200b of the variations, it is possible to mount the capacitors 240a and 240b having a large capacitance value without enlarging the size of the semiconductor devices 200a and 200b in plan view.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a transistor section including a source electrode that is provided on a first face of a semiconductor substrate and is electrically connected to a source terminal, a drain electrode that is provided on a second face opposite to the first face in the semiconductor substrate and is electrically connected to a drain terminal, and a gate electrode that is provided between the source electrode and the drain electrode;
a gate electrode pad that is provided on the first face;
a gate connection member that electrically connects the gate electrode pad and a gate terminal;
a gate circuit section that is provided on the first face and is electrically connected between the gate electrode pad and the gate electrode; and
a casing that accommodates the transistor section, the gate electrode pad, and the gate circuit section,
the gate circuit section including,
a capacitor,
a resistive element that is connected to the capacitor in parallel,
a first connection member that electrically connects one electrode of the capacitor to the gate electrode pad, and
a second connection member that electrically connects the other electrode of the capacitor to the gate electrode.

2. The device according to claim 1,
wherein in plan view,
the transistor section, the gate electrode pad, the capacitor, and the resistive element are disposed so as not to overlap each other,
the capacitor is disposed adjacent to the gate electrode pad, and
the first connection member is provided between the gate electrode pad and the capacitor.

3. The device according to claim 2,
wherein the capacitor is disposed adjacent to the transistor section, and
the second connection member is provided between the capacitor and the transistor section.

4. The device according to claim 1,
wherein an inductance value of a series circuit of the gate connection member, the first wiring, and the second wiring is less than 8 nH.

5. The device according to claim 1,
wherein the transistor section includes,
a drift layer of a first conductivity type which is provided on the first face,
a base layer of a second conductivity type which is provided on the drift layer,
a source layer of the first conductivity type which is selectively provided on the base layer, and
a gate electrode that faces a part of the drift layer and the base layer through a gate insulating film,
the semiconductor substrate contains an impurity of the first conductivity type,
the source electrode is electrically connected to the base layer and the source layer on the base layer and on the source layer, and
the capacitor includes,
a first capacitor electrode that is electrically connected to the gate electrode pad through the first wiring,
a second capacitor electrode that is electrically connected to the gate electrode through the second wiring, and
a dielectric film that is provided between the first capacitor electrode and the second capacitor electrode.

6. The device according to claim 5,
wherein the first capacitor electrode is provided on the drift layer through a first insulating layer,
the dielectric layer is provided on the first capacitor electrode, and
the second capacitor electrode is provided on the dielectric layer.

7. The device according to claim 5,
wherein the transistor section includes a conductive body that extends in the drift layer,
the conductive body includes a conductive body that faces the drift layer through a first insulating film, and faces the gate electrode through a second insulating film,
the first capacitor electrode faces a part of the drift layer through a third insulating film, and
the second capacitor electrode extends in the drift layer, faces the drift layer through a fourth insulating film, and faces the first capacitor electrode through the dielectric layer.

8. The device according to claim 7,
wherein the capacitor includes the base layer on the drift layer, and
the first capacitor electrode faces a part of the drift layer and the base layer.

9. The device according to claim 1,
wherein the capacitor and the resistive element are disposed on the gate electrode pad through the first connection member and are electrically connected to the gate electrode pad.

10. The device according to claim 9,
wherein the first connection member is provided between the capacitor and the gate electrode pad.

11. The device according to claim 2,
wherein an inductance value of a series circuit of the gate connection member, the first wiring, and the second wiring is less than 8 nH.

12. The device according to claim 3,
wherein an inductance value of a series circuit of the gate connection member, the first wiring, and the second wiring is less than 8 nH.

13. The device according to claim 2,
wherein the transistor section includes,
a drift layer of a first conductivity type which is provided on the first face,
a base layer of a second conductivity type which is provided on the drift layer,
a source layer of the first conductivity type which is selectively provided on the base layer, and
a gate electrode that faces a part of the drift layer and the base layer through a gate insulating film,
the semiconductor substrate contains an impurity of the first conductivity type,
the source electrode is electrically connected to the base layer and the source layer on the base layer and on the source layer, and
the capacitor includes,
a first capacitor electrode that is electrically connected to the gate electrode pad through the first wiring,
a second capacitor electrode that is electrically connected to the gate electrode through the second wiring, and
a dielectric film that is provided between the first capacitor electrode and the second capacitor electrode.

14. The device according to claim 3,
wherein the transistor section includes,
a drift layer of a first conductivity type which is provided on the first face,
a base layer of a second conductivity type which is provided on the drift layer,
a source layer of the first conductivity type which is selectively provided on the base layer, and
a gate electrode that faces a part of the drift layer and the base layer through a gate insulating film,
the semiconductor substrate contains an impurity of the first conductivity type,
the source electrode is electrically connected to the base layer and the source layer on the base layer and on the source layer, and
the capacitor includes,
a first capacitor electrode that is electrically connected to the gate electrode pad through the first wiring,
a second capacitor electrode that is electrically connected to the gate electrode through the second wiring, and
a dielectric film that is provided between the first capacitor electrode and the second capacitor electrode.

15. The device according to claim 4,
wherein the transistor section includes,
a drift layer of a first conductivity type which is provided on the first face,
a base layer of a second conductivity type which is provided on the drift layer,
a source layer of the first conductivity type which is selectively provided on the base layer, and
a gate electrode that faces a part of the drift layer and the base layer through a gate insulating film,
the semiconductor substrate contains an impurity of the first conductivity type,
the source electrode is electrically connected to the base layer and the source layer on the base layer and on the source layer, and
the capacitor includes,
a first capacitor electrode that is electrically connected to the gate electrode pad through the first wiring,
a second capacitor electrode that is electrically connected to the gate electrode through the second wiring, and
a dielectric film that is provided between the first capacitor electrode and the second capacitor electrode.

16. The device according to claim 1,
wherein the semiconductor substrate contains Si.

17. The device according to claim 5,
wherein the first capacitor electrode and the second capacitor electrode contain one of polycrystalline Si, Al, Cu, or Ti.

18. The device according to claim 5,
wherein the capacitor includes,
a first capacitor electrode with a trench formed on the first capacitor,
a dielectric film disposed on a wall of the trench, and
a second capacitor electrode disposed on the first capacitor electrode through the dielectric films.

19. The device according to claim 18,
wherein the capacitor and the resistive element cover the gate electrode pad and a part of the source electrode adjacent to the gate electrode pad.

20. The device according to claim 18,
wherein the capacitor includes a silicon capacitor.
